(19) United States
(12) Patent Application Publication
(10) Pub. No.: US 2025/0383312 A1
(43) Pub. Date: Dec. 18, 2025

(54) DEVICE FOR MEASURING DIELECTRIC CONSTANT AND METHOD OF MEASURING DIELECTRIC CONSTANT USING THE SAME

(71) Applicant: Samsung Display Co., Ltd., Yongin-si (KR)

(72) Inventors: Yeonguk Kim, Yongin-si (KR); Heeyeon Park, Yongin-si (KR); Hyein Jung, Yongin-si (KR); Changyeong Song, Yongin-si (KR); Gihoon Yang, Yongin-si (KR); Yongchan Ju, Yongin-si (KR); Jaeheung Ha, Yongin-si (KR)

(21) Appl. No.: 19/048,744

(22) Filed: Feb. 7, 2025

(30) Foreign Application Priority Data
Jun. 18, 2024 (KR) 10-2024-0079075

(51) Int. Cl. G01N 27/22

(52) U.S. Cl. CPC G01N 27/221; G01N 27/226

(57) ABSTRACT

A device and a method to accurately measure a dielectric constant of a dielectric are disclosed. The method may include immersing a part of the device, the part including a micro-channel, in a container containing a liquid dielectric and waiting for a set time, curing the liquid dielectric that entered the micro-channel, and measuring the dielectric constant of the dielectric inside the micro-channel.

### CROSS-REFERENCE TO RELATED APPLICATION

The present application claims priority to and the benefit of Korean Patent Application No. 10-2024-0079075, filed on Jun. 18, 2024, in the Korean Intellectual Property Office, the entire disclosure of which is incorporated herein by reference.

### BACKGROUND

### 1. Field

One or more embodiments of the present disclosure relate to a device to measure a dielectric constant and a method of measuring a dielectric constant using the device. For example, one or more embodiments of the present disclosure relate to a method and device to accurately measure the dielectric constant of a dielectric.

### 2. Description of the Related Art

The dielectric constant is a material constant that represents the magnitude of polarization that a dielectric creates in response to an external electric field. In the International System of Units, the unit of the dielectric constant is F/m. The higher the dielectric constant is, the greater the polarization of the dielectric is, and the smaller the electric field inside the dielectric is.

In micro processes, such as semiconductor and display manufacturing processes, capacitors are increasingly used. As a result, it is desirable to control capacitance values precisely according to user specifications. For this purpose, the dielectric constant of a dielectric used in a capacitor should be accurately or suitably measured.

### SUMMARY

One or more aspects of embodiments of the present disclosure are directed toward a device and a method to accurately measure a dielectric constant of a dielectric. However, embodiments of the present disclosure are examples, the present disclosure is not limited thereto, and the present disclosure is defined by the scope of the appended claims and equivalents thereof.

Additional aspects of embodiments will be set forth in part in the description which follows and, in part, will be apparent from the description, or may be learned by practice of the presented embodiments of the disclosure.

According to one or more embodiments, a method of measuring a dielectric constant may include immersing a part of a device to measure a dielectric constant, the part including a micro-channel, in a container containing a dielectric in a liquid state and waiting for a set or predetermined time, curing the dielectric that entered the micro-channel, and measuring a dielectric constant of the dielectric inside the micro-channel.

The dielectric may enter the micro-channel through a capillary action.

The measuring of the dielectric constant may include measuring the dielectric constant of the dielectric in a cured state.

The micro-channel may be defined by a first substrate and a second substrate spaced and/or apart (e.g., spaced apart or separated) from each other and facing each other, and a first spacer and a second spacer that extend longitudinally between the first substrate and the second substrate.

The first spacer and the second spacer may be spaced and/or apart (e.g., spaced apart or separated) from each other in a width direction between the first substrate and the second substrate.

The dielectric may enter between the first substrate and the second substrate.

A first conductive (e.g., electrically conductive) layer may be between the dielectric and the first substrate, and a second conductive (e.g., electrically conductive) layer may be between the dielectric and the second substrate.

The measuring of the dielectric constant of the dielectric inside the micro-channel may include measuring a capacitance between the first conductive layer and the second conductive layer, and obtaining the dielectric constant of the dielectric based on the measured capacitance and a distance between the first conductive layer and the second conductive layer.

A portion of the first conductive layer and a portion of the second conductive layer may be exposed to the outside of the device that is to measure a dielectric constant.

The method of measuring a dielectric constant may further include, after the waiting for a set or predetermined time, removing the device to measure the dielectric constant from the container.

According to one or more embodiments, a device to measure a dielectric constant includes a first substrate having one side at least partially covered by a first conductive (e.g., electrically conductive) layer, a second substrate having one side at least partially covered by a second conductive (e.g., electrically conductive) layer, a first spacer between the one side of the first substrate and the one side of the second substrate, wherein the first spacer extends in a longitudinal direction of the first substrate, and a second spacer that extends in the longitudinal direction of the first substrate, is spaced and/or apart (e.g., spaced apart or separated) from the first spacer in a width direction of the first substrate, and is on a same layer as the first spacer. The one side of the first substrate is defined by a first exposed area and a first cover area, and the one side of the second substrate is defined by a second exposed layer area and a second cover area, and in a plan view, the first cover area and the second cover area overlap each other, the first exposed area is exposed to the outside, and the second exposed area is exposed to the outside.

The first conductive layer may include a first measurement area that covers at least a portion of the first exposed area and a first electrode area that covers at least a portion of the first cover area.

The second conductive layer may include a second measurement area that covers at least a portion of the second exposed area and a second electrode area that covers at least a portion of the second cover area.

The first electrode area and the second electrode area may at least partially overlap each other in a plan view.

The first spacer may be around a first edge that extends in a longitudinal direction of the first substrate, among edges of the first cover area.

The second spacer may be around a second edge that extends in a longitudinal direction of the second substrate, among edges of the second cover area.

The device may further include a dielectric between the first electrode region and the second electrode region.

The first conductive layer and the second conductive layer may each include a transparent (e.g., substantially transparent) conductive (e.g., electrically conductive) material.

The first spacer and the second spacer may each include an epoxy resin.

A distance between the first substrate and the second substrate may be about 5 micrometers or more and about 20 micrometers or less.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a diagram schematically illustrating a device to measure a dielectric constant according to one or more embodiments;

FIG. 2 is a cross-sectional view schematically illustrating a cross-section of the device taken along line A-A′ in FIG. 1;

FIG. 3 is a cross-sectional view schematically illustrating a cross-section of the device taken along line B-B′ in FIG. 1;

FIG. 4 is a perspective view schematically illustrating an example of the first substrate of FIG. 1;

FIG. 5 is a perspective view schematically illustrating an example of the second substrate of FIG. 1;

FIG. 6 is a perspective view schematically illustrating an example in which a first spacer and a second spacer are on the first substrate of FIG. 1;

FIG. 7 is a perspective view schematically illustrating an example of the device of FIG. 1;

FIG. 8 is a perspective view schematically illustrating an example in which a dielectric enters a micro-channel of the device of FIG. 7;

FIG. 9 is a cross-sectional view schematically illustrating another example of a cross-section of the device taken along line A-A″ in FIG. 1;

FIG. 10 is a cross-sectional view schematically illustrating another example of a cross-section of the device taken along line A-A′ in FIG. 1;

FIG. 11 is a diagram schematically illustrating an example in which additional spacers are further included in the device of FIG. 1;

FIG. 12 is a graph illustrating measurement results for a dielectric constant in an example in which the device according to FIG. 11 further includes a first additional spacer and a second additional spacer; and

FIG. 13 is a flowchart schematically illustrating a method of manufacturing a device to measure a dielectric constant, according to one or more embodiments.

### DETAILED DESCRIPTION

Reference will be made in more detail to one or more embodiments, examples of which are illustrated in the accompanying drawings, wherein like reference numerals refer to like elements throughout. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

As used herein, the term “and/or” includes any and all combinations of one or more of the associated listed items. Throughout the present disclosure, the expression “at least one of a, b, or c” indicates only a, only b, only c, both a and b, both a and c, both b and c, all of a, b, and c, or variations thereof.

While the subject matter of the present disclosure is capable of one or more modifications and alternative forms, embodiments thereof are shown by way of example in the drawings and will herein be described in more detail. Aspects, features, and characteristics of embodiments of the present disclosure, and realizing methods thereof will become more apparent by referring to the drawings and embodiments described in more detail below. However, the present disclosure is not limited to the embodiments disclosed hereinafter and may be realized in one or more suitable forms.

Hereinafter, one or more embodiments of the present disclosure will be described in more detail by referring to the accompanying drawings. In descriptions with reference to the drawings, the same reference numerals are given to elements that are the same or substantially the same, and descriptions may not be repeated.

If (e.g., when) elements, such as a layer, a film, an area, a plate, and/or the like, are referred to as being “on” another element, the reference may indicate not only a case where the element is “directly on” the other element, but also a case where yet another element is between the element and the other element. In contrast, if (e.g., when) an element is referred to as being “directly on” another element, there may be no intervening elements present.

If (e.g., when) one or more components, such as layers, membranes, regions, plates, and/or the like, are referred to be “under” other components, this not only refers to that the components are directly “below” other components, but also includes cases where other components are between the components. In contrast, if (e.g., when) a component is referred to as being “directly under” another component, there may be no intervening elements present.

For convenience of illustration, elements in the drawings may have exaggerated or reduced sizes. For example, sizes and thicknesses of the elements in the drawings may be randomly indicated for convenience of illustration, and thus, embodiments of the present disclosure are not necessarily limited to the illustrations of the drawings. For example, for convenience of illustration, the size, thickness, and ratio of components in the drawings may be exaggerated and/or simplified for clarity. Therefore, spatially relative terms, such as “below,” “lower,” “beneath,” “above,” “upper,” and/or the like, are used herein to easily describe the relationship between elements or features.

The terms used in the present disclosure to describe a space, a direction, and/or the like are mainly or predominantly to illustrate the space, the direction, and/or the like in the drawings, but may also be understood as describing one or more other directions or viewpoints. For example, if (e.g., when) a device or component in a figure is turned over, a device or component described as “below” may be interpreted in a different orientation (e.g., rotated 90 degrees, in the opposite direction, and/or the like). For example, if (e.g., when) a device or component in a figure is turned over, a device or component described as “on” may be interpreted as being in a different orientation (e.g., rotated 90 degrees, in the opposite direction, and/or the like). Accordingly, “below” and “on” may include both (e.g., concurrently or simultaneously) upward and downward directions. In one or more embodiments, devices or components may be oriented differently from the drawings, and descriptions of a space, a direction, and/or the like described herein may be interpreted in one or more suitable ways.

The order of processes or methods described in the present disclosure for processing, manufacturing, and/or the like may not necessarily reflect the actual order in which they are performed. For example, two processes or two methods described in succession may be performed concurrently (e.g., simultaneously) or substantially concurrently (e.g., substantially simultaneously), or may be performed in an order opposite to the order in which they are described.

In the present disclosure, the x-axis, the y-axis, and the z-axis are not limited to three axes of the rectangular coordinate system, and may be interpreted in a broader sense. For example, the x-axis, the y-axis, and the z-axis may be perpendicular (e.g., substantially perpendicular) to one another, or may represent different directions that are not perpendicular (e.g., not substantially perpendicular) to one another.

In the present disclosure, terms, such as ‘first,’ ‘second,’ ‘third,’ and/or the like, may be used to describe specific elements of the present disclosure. These terms may be used to distinguish one component from another.

If (e.g., when) a component is referred to as being “connected to” or “coupled to” another component, it should be understood that the connection or coupling may be direct or indirect.

If (e.g., when) a component is referred to as being “electrically connected” to another component, the component and the other component may be directly and electrically connected or may be indirectly and electrically connected through a conductive (e.g., electrically conductive) component.

In one or more embodiments, if (e.g., when) a component is referred to as being “between” two components, this may refer to either that it is the only component between the two components or that additional components may also be present between the two components.

The terms used in the present disclosure are used to describe specific embodiments and are not intended to limit the present disclosure. As used herein, the singular forms “a,” “an,” and “the” are intended to include the plural forms as well, unless the context clearly dictates otherwise.

For example, expressions, such as “mix,” “mixture,” “mixing,” “have,” and/or the like, indicate the presence of the described feature, integer, step, operation, element, and/or component, but do not exclude the presence or addition of one or more other features, integers, steps, operations, elements, components, and/or the like.

For example, terms, such as “substantially,” “approximately,” and similar terms are used as terms of approximation rather than precise degree. These terms describe inherent variations in measured or calculated values that would be recognized by a person of ordinary skill in the art. For example, terms, such as “may” or “can” are used to indicate that one or more embodiments disclosed herein are possible or optional.

For example, in the present disclosure, saying that one layer has the “same layer structure” as another layer may refer to that a plurality of layers included in one layer may be included in substantially the same order in another layer. For example, a plurality of layers included in one layer and a plurality of layers included in another layer may each include substantially the same material and be in substantially the same order.

Electronic or electrical devices and/or any other related devices or components (e.g., one or more of the modules) according to one or more embodiments of the present disclosure described herein may be implemented using any suitable combination of hardware, firmware (e.g., application-specific integrated circuits), and software. For example, the one or more components of these devices may be on one integrated circuit (IC) chip and/or on separate IC chips. In one or more embodiments, the one or more components of these devices may be on a flexible printed circuit film, a tape carrier package (TCP), a printed circuit board (PCB), and/or on a single substrate. In one or more embodiments, the one or more components of these devices may be implemented as processes or threads that run on one or more processors, execute computer program instructions on one or more computing devices, and interact with other system components to perform one or more suitable functions described herein.

Computer program instructions may be stored in memory, which may be implemented in a computing device using standard memory devices, such as random-access memory (RAM). Computer program instructions may also be stored on other non-transitory computer-readable media, such as, for example, a Compact Disc Read-Only Memory (CD-ROM), flash drive, and/or the like. In one or more embodiments, one skilled in the art will recognize that the functionality of one or more computing devices may be combined or integrated into a single computing device, or, in one or more embodiments, the functionality of a particular computing device may be distributed across one or more other computing devices without departing from the spirit and scope of the present disclosure.

Hereinafter, a device to measure a dielectric constant according to one or more embodiments is described in more detail.

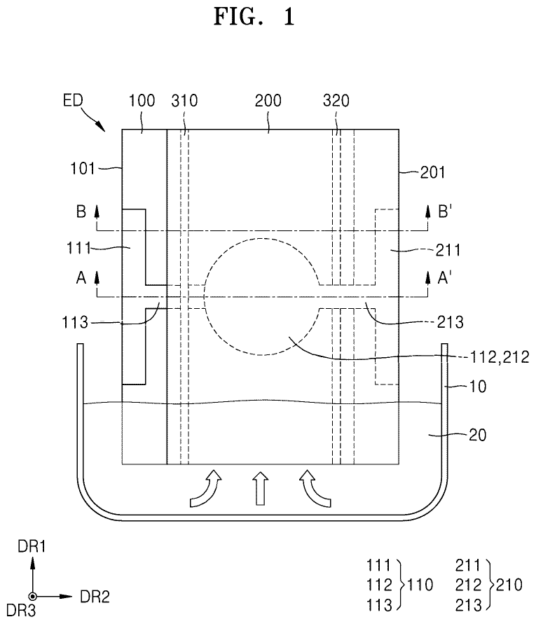

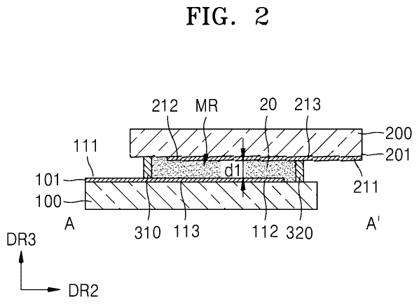

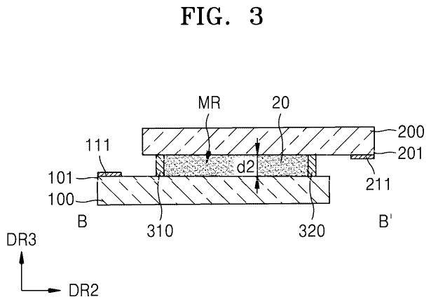

FIG. 1 is a diagram schematically illustrating a device to measure a dielectric constant according to one or more embodiments. FIG. 2 is a cross-sectional view schematically illustrating a cross section of the device taken along line A-A′ of FIG. 1. FIG. 3 is a cross-sectional view schematically illustrating a cross section of the device taken along line B-B′ of FIG. 1.

As illustrated in FIG. 1, a device ED to measure a dielectric constant may include a first substrate 100, a second substrate 200, a first conductive layer 110, a second conductive layer 210, a first spacer 310, and a second spacer 320.

The first substrate 100 and the second substrate 200 may each include glass, a metal, and/or a polymer resin, and may also each include a transparent (e.g., substantially transparent) material, such as glass. The first substrate 100 and the second substrate 200 may each include a transparent (e.g., substantially transparent) material in order to allow light to reach the internal dielectric, the first spacer 310, and/or the second spacer 320 during a photocuring process as described in one or more embodiments.

For example, the first substrate 100 and the second substrate 200 may each include polymer resins, such as polyethersulfone, polyacrylate, polyetherimide, polyethylene naphthalate, polyethylene terephthalate, polyphenylene sulfide, polyarylate, polyimide, polycarbonate, and/or cellulose acetate propionate.

The first substrate 100 may constitute one side of a micro-channel, and the second substrate 200 may constitute another side of the micro-channel. The first substrate 100 may be to face at least a portion of the second substrate 200. The first substrate 100 may be spaced and/or apart (e.g., spaced apart or separated) from the second substrate 200 by a set or predetermined distance, and the first substrate 100 may be to be parallel (e.g., substantially parallel) to the second substrate 200.

The first substrate 100 may include a first exposed area (EA1 in FIG. 3, same hereinafter) and a first cover area (CA1 in FIG. 3, same hereinafter). For example, the first exposed area EA1 may be an area exposed to the outside in the device ED. The first cover area CA1 may be covered by the first spacer 310, the second spacer 320, the second substrate 200, and/or the like in the device ED, and as a result, the first cover area CA1 may not be exposed to the outside.

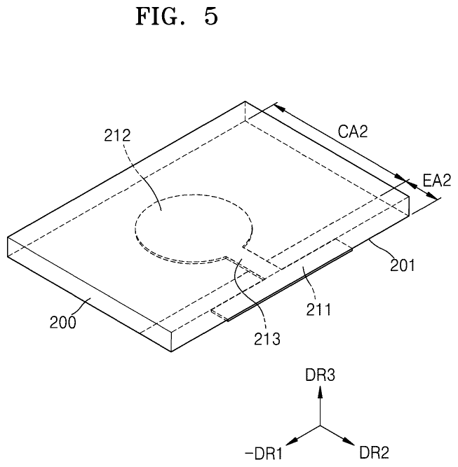

The second substrate 200 may include a second exposed area (EA2 in FIG. 5, same hereinafter) and a second cover area (CA2 in FIG. 5, same hereinafter). For example, the second exposed area EA2 may be an area exposed to the outside in the device ED. The second cover area CA2 may be covered by the first spacer 310, the second spacer 320, the first substrate 100, and/or the like in the device ED, and as a result, the second cover area CA2 may not be exposed to the outside.

The first substrate 100 and the second substrate 200 may face each other, and may only partially overlap if (e.g., when) viewed in a direction perpendicular (e.g., substantially perpendicular) to the first substrate 100. The first substrate 100 and the second substrate 200 face each other, and if (e.g., when) viewed in a direction perpendicular (e.g., substantially perpendicular) to the first substrate 100, edges of the first substrate 100 and the second substrate 200 that extend in a longitudinal direction may not overlap or may be offset from each other.

For example, if (e.g., when) viewed in a direction perpendicular (e.g., substantially perpendicular) to the first substrate 100, the first exposed area EA1 may not be overlapped by the second substrate 200 (or the second cover area CA2), and the first cover area CA1 may overlap the second substrate 200 (or the second cover area CA2). For example, if (e.g., when) viewed in a direction perpendicular (e.g., substantially perpendicular) to the first substrate 100, the second exposed area EA2 may not be overlapped by the first substrate 100, the second cover area CA2 may overlap the first substrate 100.

The first conductive layer 110 may be on the first substrate 100. For example, the first conductive layer 110 may cover at least a portion of one side of the first substrate 100. The first conductive layer 110 may include a conductive (e.g., electrically conductive) material. For example, the first conductive layer 110 may include a transparent (e.g., substantially transparent) conductive (e.g., electrically conductive) material, such as indium zinc gallium oxide (IZGO) and/or indium zinc oxide (IZO).

The first conductive layer 110 may include a first measurement area 111 on the first exposed area EA1 on one side of the first substrate 100. The first measurement area 111 may cover at least a portion of the first exposed area EA1. The first measurement area 111 may be exposed to the outside of the device ED, allowing for a first probe that is to measure a capacitance to come in contact with the first measurement area 111. For example, a portion of the first conductive layer 110 may be exposed to the outside of the device ED, and a first probe to measure a capacitance may come in contact with this exposed part.

The first conductive layer 110 may include a first electrode area 112 on the first cover area CA1 on one side of the first substrate 100. The first electrode area 112 may cover at least a portion of the first cover area CA1. The first cover area CA1 may not be exposed to the outside in the device ED, and the first cover area CA1 may be in direct contact with the dielectric if (e.g., when) the dielectric enters the micro-channel.

The first conductive layer 110 may further include a first connection area 113 that electrically connects the first measurement area 111 to the first electrode area 112. The first connection area 113 may be to span both the first exposed area EA1 and the first cover area CA1 or may be only in the first cover area CA1. The first connection area 113 may cover a portion of the first exposed area EA1 and a portion of the first cover area CA1 or may cover only a portion of the first cover area CA1.

In one or more embodiments, the first conductive layer 110 may include a first measurement area 111 that covers at least a portion of the first exposed area EA1 and a first electrode area 112 that covers at least a portion of the first cover area CA1.

The second conductive layer 210 may include a second measurement area 211 on the second exposed area EA2 on one side of the second substrate 200. The second measurement area 211 may cover at least a portion of the second exposed area EA2. The second measurement area 211 may be exposed to the outside from the device ED, and a second probe to measure a capacitance may come in contact with the second measurement area 211. For example, a portion of the second conductive layer 210 may be exposed to the outside of the dielectric constant measurement device ED, and a second probe to measure a capacitance may come in contact with this exposed portion of the second conductive layer 210.

For example, one side of the second substrate 200 may refer to a side facing one side of the first substrate 100. The one side of the first substrate 100 and the one side of the second substrate 200 may be to face each other and may be spaced and/or apart (e.g., spaced apart or separated) from each other by a set or predetermined distance.

The second conductive layer 210 may include a second electrode area 213 on the second cover area CA2 on one side of the second substrate 200. The second electrode area 213 may cover at least a portion of the second cover area CA2. The second cover area CA2 may not be exposed to the outside in the device ED, and the second cover area CA2 may come in direct contact with the dielectric if (e.g., when) the dielectric enters the micro-channel.

The second conductive layer 210 may further include a second connection area 212 that electrically connects the second measurement area 211 and the second electrode area 213. The second connection area 212 may be to span both the second exposed area EA2 and the second cover area CA2 or may be only in the second cover area CA2. The second connection area 212 may cover a portion of the second exposed area EA2 and a portion of the second cover area CA2 or may cover only a portion of the second cover area CA2.

In one or more embodiments, the second conductive layer 210 may include a second measurement area 211 that covers at least a portion of the second exposed area EA2 and a second electrode area 213 that covers at least a portion of the second cover area CA2. In one or more embodiments, the first electrode area 112 of the first conductive layer 110 and the second electrode area 213 of the second conductive layer 210 may at least partially overlap in a plan view.

A first pattern of the first conductive layer 110 may refer to a shape of the first conductive layer 110 including the first measurement area 111, the first electrode area 112, and the first connection area 113. A second pattern of the second conductive layer 210 may refer to a shape of the second conductive layer 210 including the second measurement area 211, the second electrode area 213, and the second connection area 212.

The first spacer 310 may be between the first substrate 100 and the second substrate 200 and may serve to adhere the first substrate 100 to the second substrate 200. For example, the first spacer 310 may include an epoxy resin. The first spacer 310 may be defined as an epoxy resin applied on one side of the first substrate 100 and/or one side of the second substrate 200. The epoxy resin may be cured through processes, such as photocuring and/or thermal curing. As a result, the first spacer 310 may separate the first substrate 100 and the second substrate 200 by a height of the first spacer 310, while also fixing the first substrate 100 and the second substrate 200 to face each other.

For example, the first spacer 310 may extend in the longitudinal direction of the first substrate 100 if (e.g., when) viewed from a vertical (e.g., substantially vertical) direction of the first substrate 100 (e.g., plan view). The first spacer 310 may be around the first edge 101 that extends in the longitudinal direction of the first substrate 100, among the edges of the first cover area CA1.

For example, the first spacer 310 may be parallel (e.g., substantially parallel) to the first edge 101 that extends in the longitudinal direction, among the edges of the first substrate 100. The first spacer 310 may serve as a boundary to distinguish the first exposed area EA1 from the first cover area CA1 of the first substrate 100. The first edge 101 may refer to an edge in the first exposed area EA1, among the edges of the first substrate 100.

The second spacer 320 may be between the first substrate 100 and the second substrate 200, and may serve to adhere the first substrate 100 and the second substrate 200 together with the first spacer 310. For example, the second spacer 320 may include an epoxy resin. The second spacer 320 may be defined as an epoxy resin applied on one side of the first substrate 100 and/or one side of the second substrate 200. The epoxy resin may be cured through processes, such as photocuring and/or thermal curing. As a result, the second spacer 320 may separate the first substrate 100 and the second substrate 200 by a height of the second spacer 320, while also fixing the first substrate 100 and the second substrate 200 to face each other. For example, after curing, the height of the first spacer 310 may be substantially equal to the height of the second spacer 320.

For example, the second spacer 320 may extend in the longitudinal direction of the first substrate 100 if (e.g., when) viewed from a vertical (e.g., substantially vertical) direction of the first substrate 100 (e.g., plan view). The second spacer 320 may be around the second edge 201 that extends in the longitudinal direction of the second substrate 200, among the edges of the second cover area CA2.

For example, the second spacer 320 may be parallel (e.g., substantially parallel) to the first edge 101 that extends in the longitudinal direction, among the edges of the first substrate 100. The second spacer 320 may be spaced and/or apart (e.g., spaced apart or separated) from the first spacer 310 in the width direction of the first substrate 100. The width direction and the length direction may refer to directions that intersect each other perpendicularly (e.g., substantially perpendicularly). If (e.g., when) the longitudinal directions of the first substrate 100 and the second substrate 200 are parallel (e.g., substantially parallel), the second spacer 320 may be parallel (e.g., substantially parallel) to the second edge 201 that extends in the longitudinal direction among the edges of the second substrate 200. The second spacer 320 may serve as a boundary to distinguish the second exposed area EA2 and the second cover area CA2 of the second substrate 200. The second edge 201 may refer to an edge in the second exposed area EA2, among the edges of the second substrate 200.

As illustrated in FIG. 1, a part of the device ED may be in a container 10 containing a dielectric 20 in a liquid state. The dielectric 20 in a liquid state may enter the micro-channel by a capillary action.

The device ED may further include a micro-channel. For example, a method of measuring a dielectric constant using the device ED may include a step of immersing a part of the device ED, the part including the micro-channel, into the container 10 containing the dielectric 20 in a liquid state, and a step of waiting for a set or predetermined time. The step of waiting may proceed for a set or predetermined amount of time or until the dielectric enters to a set or predetermined height in the micro-channel.

For example, after the step of waiting, the method may further include removing the device ED from the container 10 containing the liquid dielectric 20.

For example, the method may further include curing the dielectric that entered the micro-channel by the capillary action, and measuring the dielectric constant of the dielectric inside the micro-channel.

The dielectric 20 in a liquid state may be cured through a photocuring process. After the dielectric is cured, the dielectric constant may be measured based on a capacitance of the device ED. If (e.g., when) the capacitance is measured, the dielectric constant may be obtained using Equation 1 as described in one or more embodiments. In one or more embodiments, the obtained dielectric constant may refer to the dielectric constant of the dielectric in a cured state.

For example, the step of measuring the dielectric constant may include measuring a capacitance between the first conductive layer 110 and the second conductive layer 210, and obtaining the dielectric constant of the dielectric based on this capacitance and the distance between the first conductive layer 110 and the second conductive layer 210. The capacitance and the distance between the first conductive layer 110 and the second conductive layer 210 may be values to be substituted into Equation 1 as described in one or more embodiments.

As illustrated in FIGS. 1-3, the micro-channel (for example, a micro flow path) in the device ED may be defined by the first substrate 100, the second substrate 200, the first spacer 310, and the second spacer 320. For example, the micro-channel may be defined as an empty space provided by the first substrate 100, the second substrate 200, the first spacer 310, and the second spacer 320. The first conductive layer 110 may cover at least a portion of one side of the first substrate 100 and may directly contact the dielectric that entered the micro-channel. In one or more embodiments, the second conductive layer 210 may cover at least a portion of one side of the second substrate 200 and may directly contact the dielectric that entered the micro-channel.

In FIG. 2, the first conductive layer 110 and the second conductive layer 210 may be spaced and/or apart (e.g., spaced apart or separated) from each other by a first distance d1. The first distance d1 may be used to obtain the dielectric constant of the dielectric by substituting the first distance d1 in Equation 1 (e.g., d1 of FIG. 2 may be d in Equation 1).

$$C = \frac{{ε}_{0} \times {ε}_{r} \times A}{d} \qquad Equation 1$$

In Equation 1, C is the capacitance, co is the permittivity of vacuum, co is the dielectric constant of the medium, A is the area of the electrode, and d is the distance between the electrodes. The first distance d1 between the first conductive layer 110 and the second conductive layer 210 may be a value corresponding to d in Equation 1. C may be a capacitance value measured through the first measurement area 111 and the second measurement area 211. A may represent the area of the first electrode area 112 or the area of the second electrode area 213. The first electrode area 112 and the second electrode area 213 may be designed to have substantially the same shape and area.

As such, in the device ED according to one or more embodiments, the distance between the first conductive layer 110 and the second conductive layer 210 (e.g., between the first electrode area 112 and the second electrode area 213), which serve as two electrodes of a capacitor, may be a constant value. As the distance between the first conductive layer 110 and the second conductive layer 210 (e.g., between the first electrode area 112 and the second electrode area 213) is fixed, the value of d in Equation 1 may remain constant regardless of the dielectric that entered the micro-channel of the dielectric constant measurement device ED. As a result, an error in measuring the capacitance, which is sensitive with respect to a thickness of the dielectric, may be minimized or reduced.

A device to measure a dielectric constant according to a comparative example, which is not an embodiment of the present disclosure, may be manufactured in the following manner.
Providing a dielectric layer on one electrode of a capacitor;
Curing the dielectric layer; and
Providing another electrode of the capacitor on the dielectric layer.

In one or more embodiments, during the process of providing the other electrode of the capacitor through a process, such as deposition on the dielectric layer, there may be a high likelihood that wrinkles occur on the dielectric surface. The wrinkles may cause errors in a height of the dielectric layer, and as a result, errors may also occur in the measured capacitance. Errors in the measured capacitance may cause errors in the measured dielectric constant.

In one or more embodiments, in order to accurately measure the dielectric constant, the exact thickness of the dielectric layer may be important. For the device according to the comparative example, providing a dielectric layer at a correct or desired thickness on one electrode is difficult.

In one or more embodiments, the following effects may occur by using the device ED according to one or more embodiments.

First, as the dielectric enters the micro-channel with a fixed thickness through a capillary action, a dielectric layer having an accurate thickness may be easily provided.

Second, because the deposition process is omitted, wrinkles may not occur on the dielectric surface. As a result, both a precise capacitance and a precise dielectric constant may be measured or obtained.

As illustrated in FIG. 3, one side of the first substrate 100 and one side of the second substrate 200 may be spaced and/or apart (e.g., spaced apart or separated) from each other by a second distance d2. The second distance d2 may be greater than the first distance d1 by a thickness of the first conductive layer 110 and a thickness of the second conductive layer 210. The second distance d2 may refer to a thickness of the micro-channel and may be a factor that affects the capillary action. For example, the thickness (e.g., the second distance) of the micro-channel may be about 30 micrometers or less, and for example, may be about 5 micrometers to about 20 micrometers.

If (e.g., when) the second distance d2 is less than 5 micrometers, the thickness may be too small to allow smooth entering of the dielectric. If (e.g., when) the second distance d2 is greater than 20 micrometers, the capillary action may not sufficiently occur, and the entering of the dielectric may not be smooth.

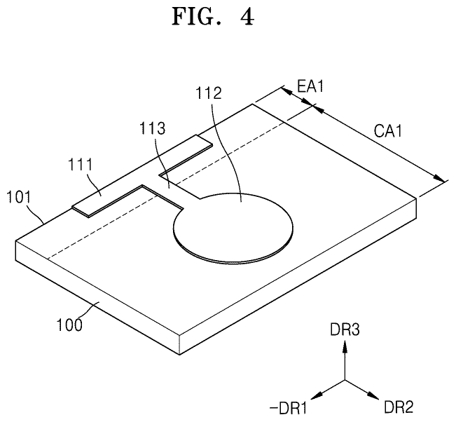

FIG. 4 is a perspective view schematically illustrating an example of the first substrate of FIG. 1.

As illustrated in FIG. 4, the first measurement area 111, the first electrode area 112, and the first connection area 113 may be on an upper surface of the first substrate 100. The term “upper surface” of the first substrate 100 may be used for convenience of illustration, and may be considered as the “bottom surface” depending on the viewing direction.

The first electrode area 112 may be at or around a center of the first substrate 100 or may be at a center or around the first cover area CA1. For example, the first electrode area 112 may have one or more shapes, such as a circular (e.g., substantially circular), oval (e.g., substantially oval), or square (e.g., substantially square) shape, and the circular first electrode area 112 in FIG. 4 is an example. The first measurement area 111 may be around the first edge 101 for convenience of measurement. The first measurement area 111 may be in the first exposed area EA1.

FIG. 5 is a perspective view schematically illustrating an example of the second substrate of FIG. 1.

As illustrated in FIG. 5, the second measurement area 211, the second electrode area 213, and the second connection area 212 may be on a lower surface of the second substrate 200. The term “lower surface” of the second substrate 200 may be used for convenience of illustration and may be considered as the “upper surface” depending on the viewing direction.

The second electrode area 213 may be at or around a center of the second substrate 200 or may be at a center or around the second cover area CA2. For example, the second electrode area 213 may have one or more shapes, such as a circular (e.g., substantially circular), oval (e.g., substantially oval), or square (e.g., substantially square) shape, and the circular second electrode area 213 in FIG. 5 is an example. The second measurement area 211 may be around the second edge 201 for convenience of measurement. The second measurement area 211 may be in the second exposed area EA2.

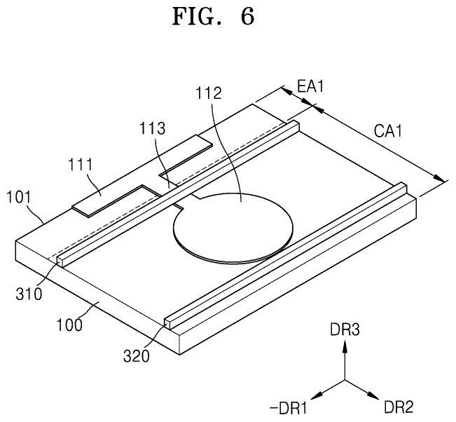

FIG. 6 is a perspective view schematically illustrating an example in which a first spacer and a second spacer are on the first substrate of FIG. 1.

For example, the first spacer 310 and the second spacer 320 may extend in a parallel (e.g., substantially parallel) direction. The first spacer 310 may extend in the longitudinal direction of the first substrate 100. The second spacer 320 may extend in the longitudinal direction of the first substrate 100. The first spacer 310 and the second spacer 320 may be spaced and/or apart (e.g., spaced apart or separated) from each other in the width direction of the first substrate 100.

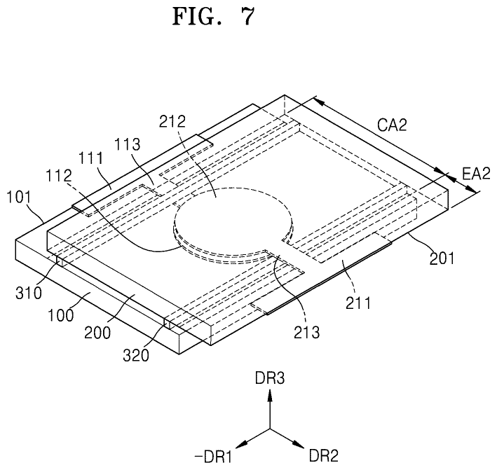

FIG. 7 is a perspective view schematically illustrating an example in which the device ED of FIG. 1 is manufactured.

As illustrated in FIG. 7, if (e.g., when) viewed in a direction perpendicular (e.g., substantially perpendicular) to the first substrate 100, the first electrode area 112 and the second electrode area 213 may overlap. If (e.g., when) viewed in a direction perpendicular (e.g., substantially perpendicular) to the first substrate 100, the first electrode area 112 may overlap at least a portion of the second electrode area 213. The second substrate 200 may be on the first substrate 100 so that the first electrode area 112 and the second electrode area 213 overlap in a plan view. The second substrate 200 may be on the first spacer 310 and the second spacer 320. After the second substrate 200 is provided on the first spacer 310 and the second spacer 320, a curing process may be performed on the first spacer 310 and the second spacer 320, which include an epoxy resin.

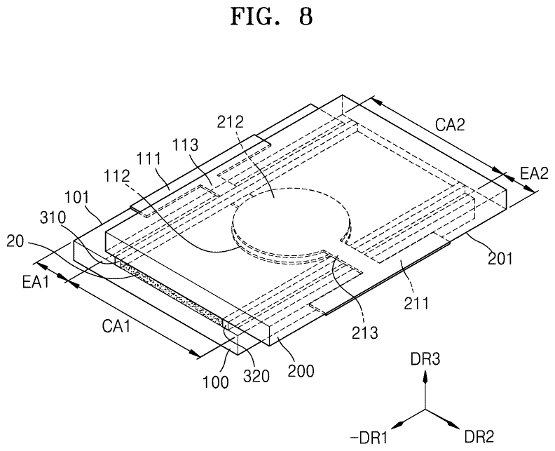

FIG. 8 is a perspective view schematically illustrating an example in which a dielectric enters a micro-channel of the device ED in FIG. 7.

In one or more embodiments, the micro channel may be defined by the first substrate 100, the second substrate 200, the first spacer 310, and the second spacer 320. As illustrated in FIG. 1, a part of the device ED or a part of the micro-channel of the device ED may be in the dielectric 20 in a liquid state in the container 10. In one or more embodiments, the micro-channel may be a channel having an inlet and an outlet, and the inlet of the micro-channel may be immersed in the dielectric 20 in a liquid state. A capillary action may occur due to a suitably minute thickness of the micro-channel. By the capillary action, the dielectric 20 in a liquid state may enter the micro-channel through the inlet of the micro-channel. Thereafter, the dielectric injected into the micro-channel may be cured through a photocuring process and/or a thermal curing process.

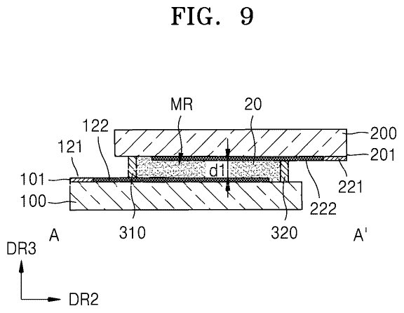

FIG. 9 is a cross-sectional view schematically illustrating another example of a cross-section of the device ED taken along line A-A′ in FIG. 1.

As illustrated in FIG. 9, the first conductive layer 110 may include a 1st-1 conductive layer 121 that includes a metal material and a 1st-2 conductive layer 122 that includes a transparent (e.g., substantially transparent) conductive (e.g., electrically conductive) material and is provided on substantially the same layer as the 1st-1 conductive layer 121. The 1st-1 conductive layer 121 and the 1st-2 conductive layer 122 may be in direct contact with each other to conduct electricity.

For example, the 1st-1 conductive layer 121 may include at least one metal selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). For example, the 1st-2 conductive layer 122 may include a transparent (e.g., substantially transparent) conductive (e.g., electrically conductive) material, such as IZGO and/or IZO.

The 1st-1 conductive layer 121 and the 1st-2 conductive layer 122 may be

on substantially the same layer. The 1st-2 conductive layer 122 may correspond to the first measurement area 111 as described in one or more embodiments. The 1st-1 conductive layer 121 may correspond to the first electrode area 112 as described in one or more embodiments or may correspond to the first electrode area 112 and the first connection area 113.

As illustrated in FIG. 9, the second conductive layer 210 may include a 2nd-1 conductive layer 221 that includes a metal material and a 2nd-2 conductive layer 222 that includes a transparent (e.g., substantially transparent) conductive (e.g., electrically conductive) material and is on substantially the same layer as the 2nd-1 conductive layer 221.

For example, the 2nd-1 conductive layer 221 may include at least one metal selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). For example, the 2nd-2 conductive layer 222 may include a transparent (e.g., substantially transparent) conductive (e.g., electrically conductive) material, such as IZGO and/or IZO.

The 2nd-1 conductive layer 221 and the 2nd-2 conductive layer 222 may be on substantially the same layer. The 2nd-2 conductive layer 222 may correspond to the second measurement area 211 as described in one or more embodiments. The 2nd-1 conductive layer 221 may correspond to the second electrode area 213 as described in one or more embodiments or may correspond to the second electrode area 213 and the second connection area 212.

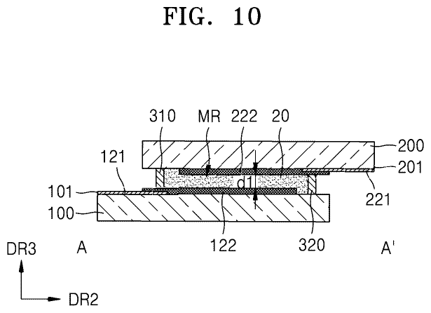

FIG. 10 is a cross-sectional view schematically illustrating another example of a cross-section taken of the device ED along line A-A′ in FIG. 1. In the description of FIG. 10, content that is substantially the same as or overlaps with that of FIG. 9 may be omitted.

As illustrated in FIG. 10, the 1st-1 conductive layer 121 and the 1st-2 conductive layer 122 may overlap vertically (e.g., substantially vertically) in one or more areas. For example, in one or more areas, the 1st-2 conductive layer 122 may cover a portion of the 1st-1 conductive layer 121. The area where the 1st-1 conductive layer 121 and the 1st-2 conductive layer 122 overlap may correspond to the first connection area 113 as described in one or more embodiments.

The 2nd-1 conductive layer 221 and the 2nd-2 conductive layer 222 may overlap vertically (e.g., substantially vertically) in one or more areas. For example, in one or more areas, the 2nd-2 conductive layer 222 may cover a portion of the 2nd-1 conductive layer 221. The area where the 2nd-1 conductive layer 221 and the 2nd-2 conductive layer 222 overlap may correspond to the second connection area 212 as described in one or more embodiments.

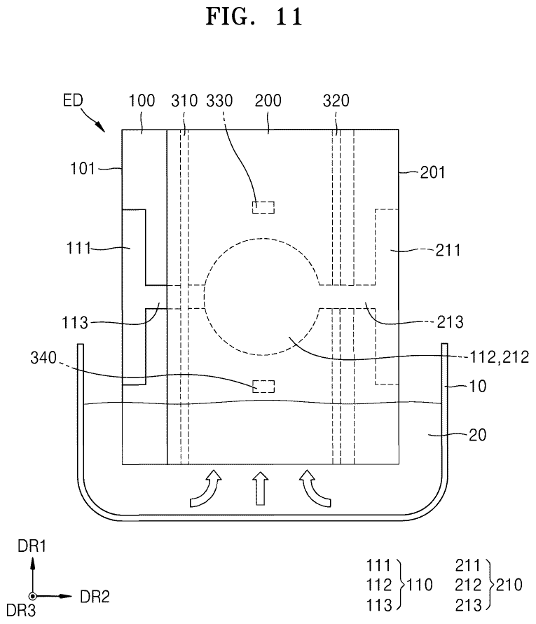

FIG. 11 is a diagram schematically illustrating an example in which additional spacers are further included in the device ED of FIG. 1. In FIG. 11, content that is substantially the same or overlapping with the content described above may be omitted.

As illustrated in FIG. 11, the device ED may further include at least one additional spacer. The at least one additional spacer may be on substantially the same layer as the first spacer 310 and second spacer 320 as described in one or more embodiments and may include substantially the same material as the first spacer 310 and the second spacer 320.

For example, at least one additional spacer 330 or 340 may be around the first electrode area 112 of the first substrate 100. At least one additional spacer 330 or 340 may be between the first substrate 100 and the second substrate 200. If (e.g., when) viewed in a direction perpendicular (e.g., substantially perpendicular) to the first substrate 100 (e.g., in a plan view), the at least one additional spacer 330 or 340 may not overlap with the first conductive layer 110 and/or the second conductive layer 210. If (e.g., when) viewed in a vertical (e.g., substantially vertical) direction of the first substrate 100 (e.g., in a plan view), the at least one additional spacer 330 or 340 may be spaced and/or apart (e.g., spaced apart or separated) from each other in a longitudinal direction with respect to the first electrode area 112. A height of at least one additional spacer 330 and 340 may be substantially equal to a height of the first spacer 310 and a height of the second spacer 320 as described in one or more embodiments.

For example, the at least one additional spacer 330 or 340 may include a first additional spacer 330 and a second additional spacer 340. For example, the first additional spacer 330 and the second additional spacer 340 may be on substantially the same layer as the first spacer 310 and second spacer 320, and may include substantially the same material as the first spacer 310 and/or the second spacer 320. A height of each of the first additional spacer 330 and the second additional spacer 340 may be substantially equal to a height of the first spacer 310 and the second spacer 320.

The first additional spacer 330 and the second additional spacer 340 may be spaced and/or apart (e.g., spaced apart or separated) from each other in the longitudinal direction. For example, if (e.g., when) viewed in a direction perpendicular (e.g., substantially perpendicular) to the first substrate 100 (e.g., in a plan view), the first additional spacer 330 and the second additional spacer 340 may be between the first spacer 310 and the second spacer 320.

For example, if (e.g., when) viewed in a direction perpendicular (e.g., substantially perpendicular) to the first substrate 100 (e.g., in a plan view), an imaginary line that connects the first additional spacer 330 and the second additional spacer 340 may pass through a center of the first substrate 100 or surroundings thereof or through a center of the first cover area CA1 or the surroundings thereof.

For example, if (e.g., when) viewed in a direction perpendicular (e.g., substantially perpendicular) to the first substrate 100 (e.g., in a plan view), an imaginary line that connects the first additional spacer 330 and the second additional spacer 340 may pass through a center of the second substrate 200 or surroundings of the second substrate 200 or through the center of the second cover area CA2 or the surroundings of the second cover area CA2.

For example, if (e.g., when) viewed in a direction perpendicular (e.g., substantially perpendicular) to the first substrate 100 (e.g., in a plan view), the imaginary line that connects the first additional spacer 330 and the second additional spacer 340 may intersect with another imaginary line that connects the first measurement area 111 to the second measurement area 211 at the shortest distance.

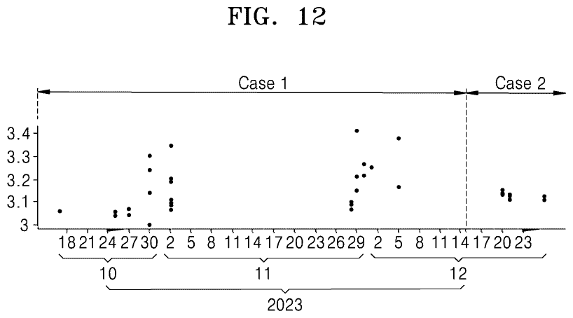

FIG. 12 is a graph illustrating measurement results of a dielectric constant in an example in which the device ED according to FIG. 11 further includes a first additional spacer and a second additional spacer.

The x-axis of the graph in FIG. 12 may represent a date on which the dielectric constant measurement was performed, and the y-axis may represent a measured dielectric constant. The dots on the graph represent individual tests, the devices ED used in the individual tests are devices having substantially the same specifications, and the dielectrics used in the individual tests are also substantially the same. Other test conditions are also substantially the same.

Referring to FIG. 12, in Case 1, the devices ED did not include the first additional spacer and the second additional spacer, and in Case 2, the devices ED included the first additional spacer and the second additional spacer. As may be seen in the graph, the dielectric constants measured in Case 1 are widely distributed approximately between 3 and 3.4. The dielectric constants measured in Case 2 are narrowly distributed around approximately 3.1. As can be seen in FIG. 12, if (e.g., when) the first additional spacer and the second additional spacer are used as in Case 2, a more accurate measurement of the dielectric constant is possible.

This may be due to the fact that the change in the distance between the first substrate 100 and the second substrate 200 may be minimized or reduced by the additional spacers 330 and 340. Because the first spacer 310 and the second spacer 320 are spaced and/or apart (e.g., spaced apart or separated) from each other in the width direction of the first substrate 100, the distance between the first substrate 100 and the second substrate 200 may be inaccurate around the centers of these substrates. The first additional spacer 330 and the second additional spacer 340 may be used to maintain the substantially constant distance between the first substrate 100 and the second substrate 200, and as a result, an accurate measurement of the dielectric constant may be performed. This may be because the distance between the two electrodes is used in Equation 1, which is the formula between the capacitance and dielectric constant.

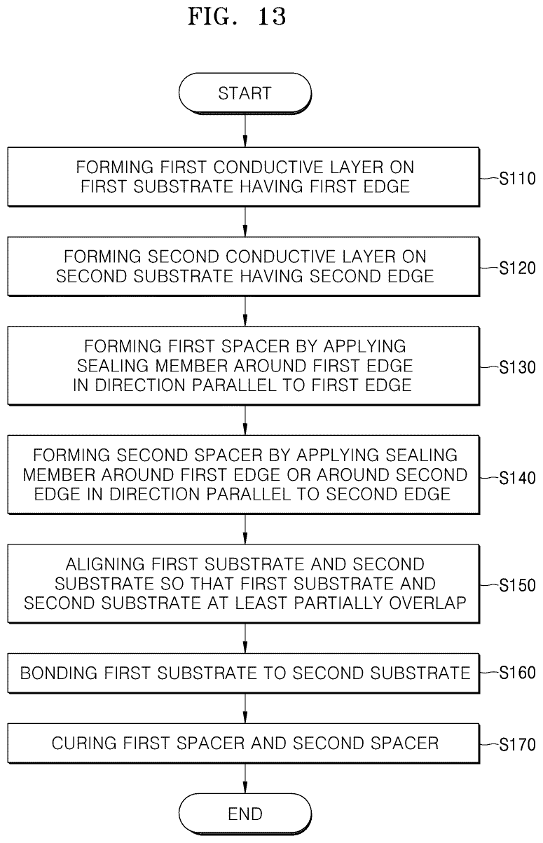

FIG. 13 is a flowchart schematically illustrating a method of manufacturing the device ED to measure a dielectric constant according to one or more embodiments. In FIG. 13, content that is substantially the same or overlapping with the content described above may be omitted.

As illustrated in FIG. 11, one or more embodiments of the method of manufacturing the device ED may include providing a first conductive layer 110 on a first substrate 100 having a first edge 101 (S110) and providing a second conductive layer 210 on the second substrate 200 having a second edge 201 (S120). Examples of patterns of each of the first conductive layer 110 and the second conductive layer 210 may be substantially the same as the patterns in FIG. 45 as described in one or more embodiments.

In one or more embodiments, the method may further include providing a first spacer 310 by applying a sealing member around the first edge 101 in a direction parallel (e.g., substantially parallel) to the first edge 101 (S130) and providing a second spacer 320 by applying a sealing member (e.g., an epoxy resin) around the first edge 101 or around the second edge 201 in a direction parallel (e.g., substantially parallel) to the second edge 201 (S140). An example of how the first spacer 310 and the second spacer 320 are provided may be substantially the same as illustrated with reference to FIG. 6.

In one or more embodiments, the method may further include aligning the first substrate 100 and the second substrate 200 so that the first substrate 100 and the second substrate 200 at least partially overlap (S150) and bonding the first substrate 100 to the second substrate 200 (S160). In one or more embodiments, the first substrate 100 and/or the second substrate 200 may include alignment marks for alignment. An aligning step (S150) may be performed based on the alignment marks. A bonding step (S160) may be performed if (e.g., when) the first substrate 100 and the second substrate 200 are aligned.

In one or more embodiments, the method may further include curing the first spacer 310 and the second spacer 320 (S170). As described in one or more embodiments, because the first spacer 310 and the second spacer 320 include an epoxy resin, after the first substrate 100 and the second substrate 200 are bonded, the first substrate 100 and the second substrate 200 may be fixed by the first spacer 310 and the second spacer 320. In one or more embodiments, the first substrate 100 and the second substrate 200 may be spaced and/or apart (e.g., spaced apart or separated) from each other by a height of the first spacer 310 and a height of the second spacer 320.

As such, the device ED manufactured by the method according to one or more embodiments may correspond to the device ED of FIGS. 1-11 as described in one or more embodiments.

According to one or more embodiments, a dielectric constant measurement device to measure an accurate dielectric constant of a dielectric and a dielectric constant measurement method using the dielectric constant measurement device may be implemented. However, the scope of the present disclosure is not limited by this effect.

Although one or more embodiments have been described, those skilled in the art will readily understand that one or more modifications may be made in the embodiments without departing from the spirit and scope of the present disclosure. Unless otherwise stated, a description of a feature or aspect within each embodiment should be considered generally applicable to other similar features or aspects of other embodiments. Accordingly, as will be more apparent to those skilled in the art, features or components described in connection with a particular embodiment may be combined with features or components described in connection with another embodiment. Therefore, the foregoing description should not be construed as being limited to one or more embodiments illustrated in the present disclosure, but should be understood as intended for combination with or application to other exemplary embodiments. Therefore, the scope of the present disclosure should be determined by the appended claims and equivalents thereof.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the appended claims and equivalents thereof.

What is claimed is:

1. A method of measuring a dielectric constant, the method comprising:
immersing a part of a device to measure a dielectric constant, the part comprising a micro-channel, into a container containing a dielectric in a liquid state and waiting for a set time;
curing the dielectric that entered the micro-channel; and
measuring a dielectric constant of the dielectric inside the micro-channel.

2. The method as claimed in claim 1, wherein:
the dielectric enters the micro-channel by a capillary action.

3. The method as claimed in claim 1, wherein:
the measuring of the dielectric constant comprises measuring the dielectric constant of the dielectric in a cured state.

4. The method as claimed in claim 1, wherein:
the micro-channel is defined by a first substrate and a second substrate spaced apart and facing each other, and a first spacer and a second spacer that extend in a longitudinal direction between the first substrate and the second substrate.

5. The method as claimed in claim 4, wherein:
the first spacer and the second spacer are spaced apart from each other in a width direction between the first substrate and the second substrate.

6. The method as claimed in claim 5, wherein:
the dielectric enters between the first substrate and the second substrate.

7. The method as claimed in claim 6, wherein:
a first conductive layer is between the dielectric and the first substrate, and a second conductive layer is between the dielectric and the second substrate.

8. The method as claimed in claim 7, wherein:
the measuring of the dielectric constant of the dielectric inside the micro-channel comprises:
measuring a capacitance between the first conductive layer and the second conductive layer; and
obtaining the dielectric constant of the dielectric based on the capacitance and a distance between the first conductive layer and the second conductive layer.

9. The method as claimed in claim 7, wherein:
a portion of the first conductive layer and a portion of the second conductive layer are exposed to outside of the device.

10. The method as claimed in claim 1, further comprising:
after the waiting for a set time, removing the device from the container.

11. A device for measuring a dielectric constant, the device comprising:
a first substrate having one side at least partially covered by a first conductive layer;
a second substrate having one side at least partially covered by a second conductive layer;
a first spacer between the one side of the first substrate and the one side of the second substrate, wherein the first spacer extends in a longitudinal direction of the first substrate; and
a second spacer that extends in the longitudinal direction of the first substrate, is spaced apart from the first spacer in a width direction of the first substrate, and is on a same layer as the first spacer,
wherein the one side of the first substrate is defined by a first exposed area and a first cover area, and the one side of the second substrate is defined by a second exposed area and a second cover area,
wherein, in a plan view, the first cover area and the second cover area overlap each other,
and the first exposed area and the second exposed area are exposed to outside.

12. The device as claimed in claim 11, wherein:
the first conductive layer comprises a first measurement area that covers at least a portion of the first exposed area, and a first electrode area that covers at least a portion of the first cover area.

13. The device as claimed in claim 12, wherein:
the second conductive layer comprises a second measurement area that covers at least a portion of the second exposed area and a second electrode area that covers at least a portion of the second cover area.

14. The device as claimed in claim 13, wherein:
the first electrode area and the second electrode area at least partially overlap each other in a plan view.

15. The device as claimed in claim 11, wherein:
the first spacer is around a first edge that extends in the longitudinal direction of the first substrate, among edges of the first cover area.

16. The device as claimed in claim 15, wherein:
the second spacer is around a second edge that extends in a longitudinal direction of the second substrate, among edges of the second cover area.

17. The device as claimed in claim 13,
further comprising a dielectric between the first electrode area and the second electrode area.

18. The device as claimed in claim 11, wherein:
the first conductive layer and the second conductive layer each comprise a transparent conductive material.

19. The device as claimed in claim 11, wherein:
the first spacer and the second spacer each comprise an epoxy resin.

20. The device as claimed in claim 11, wherein:
a distance between the first substrate and the second substrate is about 5 micrometers or more and about 20 micrometers or less.
